(19) United States
(12) Patent Application Publication
(10) Pub. No.: US 2024/0204127 A1
(43) Pub. Date: Jun. 20, 2024

(54) AVALANCHE PHOTODIODE

(71) Applicant: STMicroelectronics International N.V., Geneva (CH)

(72) Inventors: Antonin ZIMMER, Meylan (FR); Dominique GOLANSKI, Gières (FR); Sebastien PLACE, Vaulnaveys le Haut (FR); Guillaume MARCHAND, St Martin d'Hères (FR)

(73) Assignee: STMicroelectronics International N.V., Geneva (CH)

(21) Appl. No.: 18/540,625

(22) Filed: Dec. 14, 2023

(30) Foreign Application Priority Data
Dec. 20, 2022 (FR) 2214005

(51) Int. Cl. H01L 31/107; H01L 21/763; H01L 31/0288; H01L 31/18

(52) U.S. Cl. CPC H01L 31/107; H01L 21/763; H01L 31/0288; H01L 31/1804

(57) ABSTRACT

The present description concerns an avalanche photodiode comprising: a main PN junction adapted to being reverse-biased; and a plurality of semiconductor regions including at least: a first epitaxial semiconductor region of a first conductivity type; and a second semiconductor region of the second conductivity type, said second region being arranged to at least partially surround the first region, and comprising surfaces in contact with surfaces of said first region. The present description also concerns a method of manufacturing such a photodiode.

### CROSS-REFERENCE TO RELATED APPLICATION(S)

This application claims the priority benefit of French patent application number 2214005, filed on Dec. 20, 2022, entitled “Photodiode à avalanche,” which is hereby incorporated by reference to the maximum extent allowable by law.

### BACKGROUND

### Technical Field

The present disclosure generally concerns avalanche photodiodes, in particular single photon avalanche diodes, called SPAD (“Single Photon Avalanche Diode”) photodiodes and their manufacturing method.

### Description of the Related Art

A photodiode is a semiconductor component having the capacity of capturing a radiation of the optical domain and of transforming it into an electric signal.

A SPAD photodiode is a photodiode comprising a PN junction adapted to being reverse-biased at a voltage higher than the breakdown voltage, or avalanche voltage, of said junction. At this bias voltage, the electric field around the PN junction is sufficient for a photogenerated carrier reaching the space charge area, or depleted area, of the junction, to trigger an avalanche phenomenon, reflected by an increase of the current in the photodiode. In a SPAD photodiode, a single photogenerated carrier can trigger an avalanche in the depleted area by impact ionization effect.

SPAD photodiodes enable to detect radiations of very low light intensity and are particularly used for the detection of single photons and the counting of photons.

Electronic devices may comprise a plurality of photodiodes, or a plurality of pixels, each comprising at least one photodiode. For example, an image sensor is an electronic device which may comprise a plurality of photodiodes, the photodiodes enabling the image sensor to obtain image of a scene at a given time. The image is generally formed of a pixel array, each pixel comprising at least one photodiode.

The increasing miniaturization of electronic devices, particularly of image sensors, results in a miniaturization of the pixels and/or of the photodiodes.

To miniaturize a SPAD photodiode, a solution is to decrease at least one of its dimensions in the plane of the electronic circuit integrating this photodiode, for example its width. However, decreasing the width of the photodiode has a disadvantage of decreasing the photon collection volume, and thus of decreasing, in particular, the photon detection probability (“PDP”).

To compensate for this volume decrease, a solution is to increase the height of the photodiode, that is, the dimension in the direction perpendicular to the plane of the electronic circuit. However, increasing the height of the photodiode may have the disadvantage of decreasing the probability for a photogenerated carrier to reach the multiplication area, that is, the area where the electric field is sufficiently strong for impact ionization effects to take place and thus for an avalanche to occur, or of increasing the time during which the carrier can reach this multiplication area, all the more as the photogenerated carrier is at a greater distance from this multiplication area of the photodiode. Indeed, beyond a given distance from the PN junction, the electric field resulting from the reverse biasing of the PN junction cancels or strongly decreases, and does not enable as much, or even no longer enables, to drive the photogenerated carriers towards the multiplication area. Beyond a given distance from the PN junction, only the random diffusion in the photodiode can then be likely to drive the photogenerated carriers towards the multiplication area, with a non-negligible probability for the photogenerated carriers never to reach the multiplication area or to reach it with a significant delay.

As a corollary, this may increase the time jitter, which corresponds to the statistic fluctuation of the detection delay.

### BRIEF SUMMARY

There exists a need for an avalanche photodiode, for example of SPAD type, overcoming all or part of the disadvantages of known avalanche photodiodes.

In particular, there exists a need for a SPAD photodiode having a size that can be decreased without degrading the photon detection probability (PDP) and/or increasing the time jitter.

It would be advantageous to have such a photodiode without for this to complicate the method of manufacturing this photodiode, and to increase the manufacturing cost thereof.

An embodiment provides an avalanche photodiode comprising:
a main PN junction adapted to being reverse-biased; and
a plurality of semiconductor regions including at least:
   a first epitaxial semiconductor region of a first conductivity type; and
   a second semiconductor region of the second conductivity type, said second region being arranged to at least partially surround the first region, and comprising surfaces in contact with surfaces of said first region.

An embodiment provides a method of manufacturing an avalanche photodiode, comprising a main PN junction adapted to being reverse-biased, the method comprising the forming of a plurality of semiconductor regions including at least:
a first epitaxial semiconductor region of a first conductivity type; et
a second semiconductor region of the second conductivity type, said second region being arranged to at least partially surround the first region, and comprising surfaces in contact with surfaces of said first region.

According to an embodiment, the main PN junction is formed by fourth and fifth regions of the plurality of semiconductor regions;
the fourth region being heavily doped with the first conductivity type, for example more heavily doped than the first region, and being formed from a first surface of the photodiode; and
the fifth region being heavily doped with the second conductivity type, for example more heavily doped than the second region, and being formed under, and in contact with, the fourth region;
the fourth and fifth regions being for example located at the center of the photodiode in a plane parallel to the first surface.

According to an embodiment, a sixth region of the plurality of semiconductor regions is laterally formed around, and at a distance from, the fourth region from the first surface of the photodiode, the sixth region being heavily doped with the second conductivity type, for example more heavily doped than the second region.

According to an embodiment, a third semiconductor region of the plurality of semiconductor regions is formed between the first surface of the photodiode and the first region, the third region being an epitaxial region of the first conductivity type, and the fourth, fifth, and sixth regions being formed by doping, for example by ion implantation, in said third region.

According to a specific embodiment, the first and third regions are epitaxially grown and doped in similar conditions, for example corresponding to regions of a same epitaxial layer.

According to an embodiment, a guard ring region of the plurality of semiconductor regions is formed around the fourth region, the guard ring region being of the first conductivity type and being more lightly doped than the fourth region.

According to an embodiment, the semiconductor regions are formed in a well delimited by a deep trench insulation extending in a direction perpendicular to the first surface of the photodiode.

According to an embodiment, the second region comprises a lateral portion located between the first region and the deep trench insulation.

According to an embodiment, the second region comprises a buried portion located between the first region and a second surface of the photodiode opposite to the first surface.

According to an embodiment, the first region is doped in substantially constant fashion in a direction perpendicular to the first surface of the photodiode.

According to an embodiment, the first region is gradually doped in a direction perpendicular to the first surface, for example in decreasing fashion between said first surface and a second surface of the photodiode opposite to the first surface.

According to an embodiment, the first region comprises a first portion and a second portion narrower, in a plane parallel to the first surface, than the first portion, and located between the first portion and the main PN junction.

According to an embodiment, the first region surrounds the main PN junction, for example comprises a first portion located under the main PN junction, and a second portion extending all the way to the first surface of the photodiode.

According to an embodiment, the first region is inside of the second region.

According to an embodiment, each dimension of the photodiode, in a plane parallel to a first surface of the photodiode, is smaller than 6 μm and/or the height of the photodiode is in the range from 3 to 15 μm, for example in the range from 6 to 10 μm.

According to an embodiment, the forming of the plurality of semiconductor regions comprises:
the forming by epitaxial growth of an epitaxial layer of the first conductivity type intended to form the first semiconductor region; then
the forming, by partial doping of the epitaxial layer, for example by ion implantation, of at least a first portion of the second region; and
the fourth region and the fifth region are formed by partial doping of the epitaxial layer, for example by ion implantation, from the first surface of the photodiode.

According to an embodiment, the lateral portion of the second region is formed by partial doping of the epitaxial layer, for example by ion implantation, by partial change of conductivity of the epitaxial layer, by diffusion from the deep trench insulation, or by a charge-inversion material in the deep trench insulation.

According to an embodiment, the buried portion of the second region is formed by epitaxial growth, or by partial doping of the epitaxial layer, for example by ion implantation from the second surface of the photodiode.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 is a partial and simplified cross-section view showing an example of a photodiode;

FIG. 2 is a partial and simplified cross-section view showing a photodiode according to an embodiment;

FIG. 3 illustrates in very simplified fashion doping profiles in arbitrary unit of a photodiode similar to the photodiode of FIG. 2;

FIG. 4 is a partial and simplified cross-section view showing another example of a photodiode;

FIG. 5 is a partial and simplified cross-section view showing a photodiode according to another embodiment; and

FIG. 6A, FIG. 6B, FIG. 6C, FIG. 6D, FIG. 6E, FIG. 6F, and FIG. 6G are cross-section views showing steps of a method of manufacturing a photodiode according to an embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail. In particular, a SPAD photodiode generally comprises secondary circuits, particularly a circuit for biasing the PN junction to a voltage higher than its avalanche threshold, a readout circuit adapted to detecting the starting of an avalanche of the photodiode, as well as a quenching circuit having the function of interrupting the avalanche of the photodiode once it has started. These secondary circuits have not been shown in the drawings and will not be detailed, the described embodiments being compatible with secondary circuits equipping known SPAD photodiodes.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front,” “back,” “top,” “bottom,” “left,” “right,” etc., or relative positions, such as terms “above,” “under,” “upper,” “lower,” etc., or to terms qualifying directions, such as terms “horizontal,” “vertical,” etc., it is referred, unless specified otherwise, to the orientation of the drawings or to a photodiode in a normal position of use.

In the following description, a height or a depth corresponds to a dimension taken in the Z direction, which may correspond to a vertical direction, and a width corresponds to a dimension taken in the X direction, which may correspond to a horizontal direction.

Unless specified otherwise, the expressions “about,” “approximately,” “substantially,” and “in the order of” signify plus or minus 10%, preferably of plus or minus 5%.

In the following description, when reference is made to a region, it is referred to a semiconductor region.

In the following description, when reference is made to an epitaxial layer, or region, it is referred to a layer, or a region, formed by epitaxial growth.

In the examples given hereafter, it is considered that the first conductivity type is type N and the second conductivity type is type P, but the examples may also apply if the conductivity types are inverted, that is, the first conductivity type is type P and the second conductivity type is type N with, for example, appropriate anode and cathode voltage inversions.

For example, the P-type regions are doped with boron atoms (B), and/or the N-type regions are doped with arsenic atoms (As).

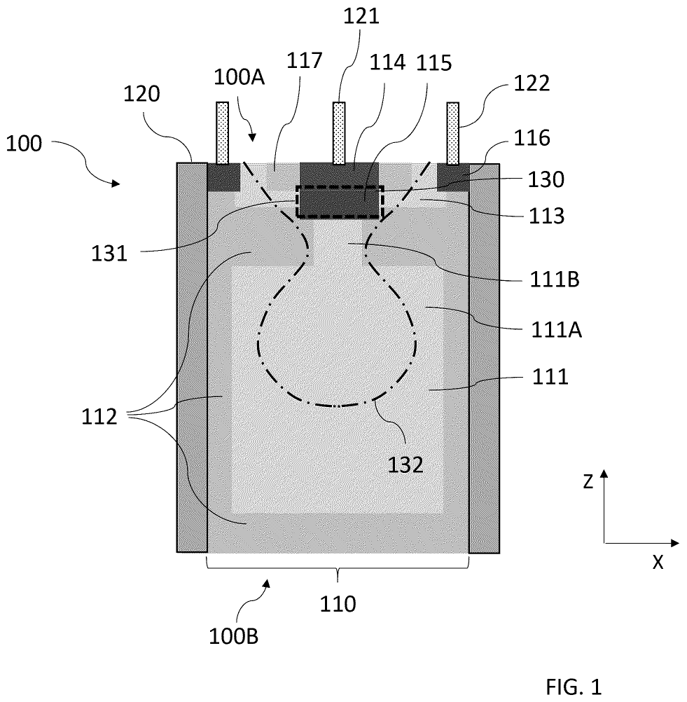

FIG. 1 is a partial and simplified cross-section view showing an example of a SPAD-type photodiode 100.

Photodiode 100 comprises a first P-type epitaxial semiconductor region 111 and a second P-type semiconductor region 112, more heavily doped than first region 111. Second region 112 surrounds first region 111.

For example, first region 111 forms a collection volume within which carriers have a significant probability of being generation on absorption of a photon (photogenerated).

Photodiode 100 further comprises a third P-type epitaxial semiconductor region 113, also less heavily doped than second region 112, flush with the upper surface 100A of photodiode 100. For example, third region 113 is epitaxially grown and doped in similar conditions as first region 111.

First region 111 may comprise a first portion 111A and a second portion 111B narrower than first portion 111A and coupling first portion 111A to third region 113.

Photodiode 100 further comprises a fourth heavily-doped N-type semiconductor region 114 flush with the upper surface 100A of photodiode 100, and a fifth heavily-doped P-type semiconductor region 115, more heavily doped than second region 112, under, and in contact with, fourth region 114.

For example, fourth region 114 has a cylindrical shape. In other words, fourth region 114 may have, in top view, a round or oval shape. Similarly, fifth region 115 may have a cylindrical shape. As a variant, the fourth region and/or the fifth region may have other shapes, for example, in top view, the shape of a quadrilateral or of a quadrilateral with rounded angles, or a substantially hemispherical shape, or may comprise a portion of substantially hemispherical shape, as shown in FIG. 4 described hereafter.

The coupling between the fourth region and the fifth region provides a top PN junction 130, or main PN junction. For a SPAD photodiode operation, the PN junction may be reverse-biased beyond the breakdown voltage, to form an electric field around this PN junction sufficient for a photogenerated carrier reaching the space charge area, or depleted area, of the PN junction, to trigger an avalanche phenomenon.

The area surrounded in dotted lines substantially corresponds to multiplication region 131, that is, a region where the electric field is sufficiently strong for the avalanche phenomenon to have a high probability of occurring.

In the shown example, a guard ring region 117 surrounds fourth region 114. The guard ring region is an N-type semiconductor region, more lightly doped than fourth region 114. For example, guard ring region 117 has the shape of a round or oval ring, the shape of a square frame or of a square frame having rounded angles.

Photodiode 100 also comprises a sixth heavily-doped P-type semiconductor region 116, more heavily doped than second region 112, flush with the upper surface 100A of the photodiode, and located around and laterally at a distance from guard ring region 117. For example, sixth region 116 has, in top view, the shape of a round or oval ring, the shape of a square frame or of a square frame with rounded angles.

Fourth region 114, fifth region 115, sixth region 116, and guard ring region 117 are generally formed by ion implantation, for example at least partially in third region 113.

Semiconductor regions 111, 112, 113, 114, 115, 116, 117 are for example made of silicon.

These semiconductor regions are located in a well 110 delimited by a deep trench insulation 120 (DTI). For example, trench 120 surrounds well 110. For example, trench 120 has, in top view, the shape of a round or oval ring, the shape of a square frame or of a square frame with rounded angles. As a variant, trench 120 has any closed shape.

Photodiode 100 also comprises a cathode 121 and an anode 122.

Cathode 121 is located in front of fourth region 114. Cathode 121 is, for example, located on top of and in contact with fourth region 114, or with a contacting area located inside or on top of fourth region 114. For example, cathode 121 substantially has a parallelepipedal or cylinder shape.

Anode 122 is located in front of sixth region 116. Anode 122 is, for example, located on top of and in contact with sixth region 116, or with a contacting area located inside or on top of sixth region 116. Preferably, anode 122 has, in top view, a shape similar to the shape of sixth region 116.

For example, for the shown photodiode, in operation, the anode is connected to ground and the bias voltage is applied to the cathode.

For example, photodiode 100 is comprised, in top view, in a square having a side length, for example, smaller than approximately 6 μm. For example, the height of photodiode 100 is in the range from approximately 3 to 15 μm, for example equal to approximately 6 μm or to approximately 10 μm.

For the miniaturization of SPAD photodiodes, for example to decrease the width of a photodiode and to compensate for this decrease by increasing the height of the photodiode, there is searched for a solution so that the increase of the height of the photodiode does not reflect as a degradation of the time jitter, and/or as a decrease in the photon detection probability (PDP).

In the example of photodiode 100, the first epitaxial region 111 comprised in second region 112, and less heavily doped with the same conductivity type as second region 112, generates a depletion area 132, schematically shown by the curve in stripe-dot lines. This depletion area defines a volume within which the transport of the carriers is substantially fast. Having the largest possible depletion volume enables to improve the time jitter over a photodiode with a lower depletion volume.

However, it can be observed that this depletion area 132 extends all the way to the center of epitaxial region 111, but that it does not reach the bottom of epitaxial region 111, that is, the bottom of the photogenerated carrier collection volume. Thus, a photogenerated carrier at the bottom of the volume may not reach multiplication region 131, or with a random and significant displacement time. A fortiori, when the height of the photodiode increases, the depletion area 132 of photodiode 100 may be insufficient to keep an acceptable time jitter. Indeed, by increasing the height of the photodiode, the depletion area remaining constant, critical areas, non-depleted and away from the multiplication area, are added at the bottom of the epitaxial region. If carriers are photogenerated in these critical areas, they may take a time all the longer to trigger an avalanche as the height increases, causing a degradation of the time jitter.

The inventors provide a photodiode and a method of manufacturing such a photodiode enabling to address the previously-described improvement needs, and to overcome all or part of the disadvantages of the previously-described photodiodes. In particular, the inventors provide a photodiode and a method of manufacturing such a photodiode enabling to increase its height without increasing the time jitter, and without decreasing the photon detection probability (PDP), or even increasing it.

Embodiments of photodiodes will be described hereafter. The described embodiments and not limiting and various variants will occur to those skilled in the art based on the indications of the present description.

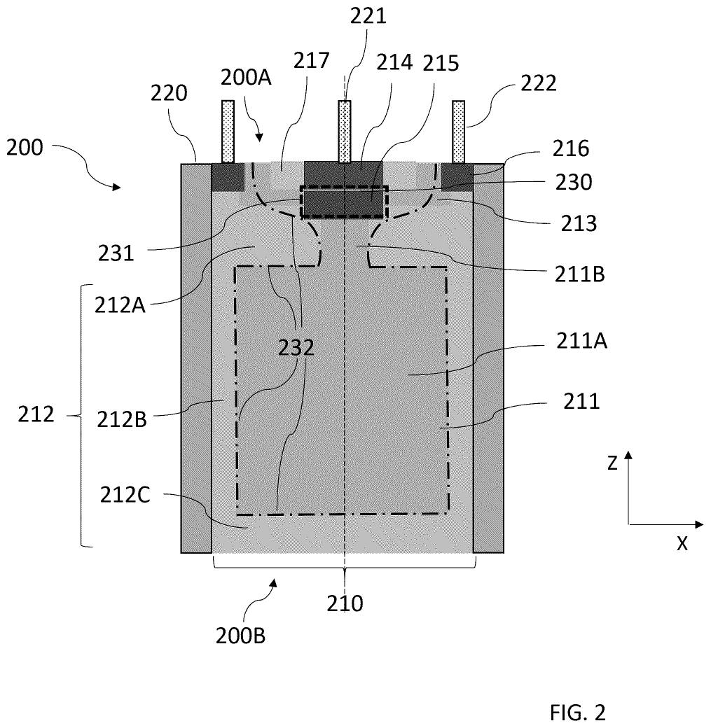

FIG. 2 is a partial and simplified cross-section view showing an avalanche photodiode 200 according to an embodiment.

According to a preferred embodiment, photodiode 200 is a SPAD-type photodiode.

Photodiode 200 has an upper surface 200A (first surface) and a lower surface 200B (second surface) opposite to the upper surface, preferably substantially parallel to the upper surface.

Photodiode 200 comprises a first epitaxial semiconductor region 211 of a first conductivity type (in the example, type N) and a second semiconductor region 212 of a second conductivity type (in the example, type P). Second region 212 surrounds, at least partially, first region 211, and comprises surfaces in contact with surfaces of first region 211. For example, first region 211 is comprised in second region 212.

Thus, photodiode 200 can be distinguished from photodiode 100 mainly in that first epitaxial region 211 is of type N, instead of being of type P.

Photodiode 200 comprises an upper semiconductor region 213 (third region) flush with the level of the upper surface 200A of photodiode 200. Third region 213 is an N-type epitaxial region.

For example, the first and third regions are epitaxially grown and doped in similar conditions, for example they correspond to regions of a same layer formed by epitaxial growth. For example, third region 213 may correspond to an upper portion (or third portion) of the layer formed by epitaxial growth.

Photodiode 200 further comprises a fourth heavily-doped N-type semiconductor region 214, preferably more heavily doped than first region 211, and flush with the upper surface 200A of photodiode 200, and a fifth heavily-doped P-type semiconductor region 215, preferably more heavily doped than second region 212, under, and in contact with, fourth region 214.

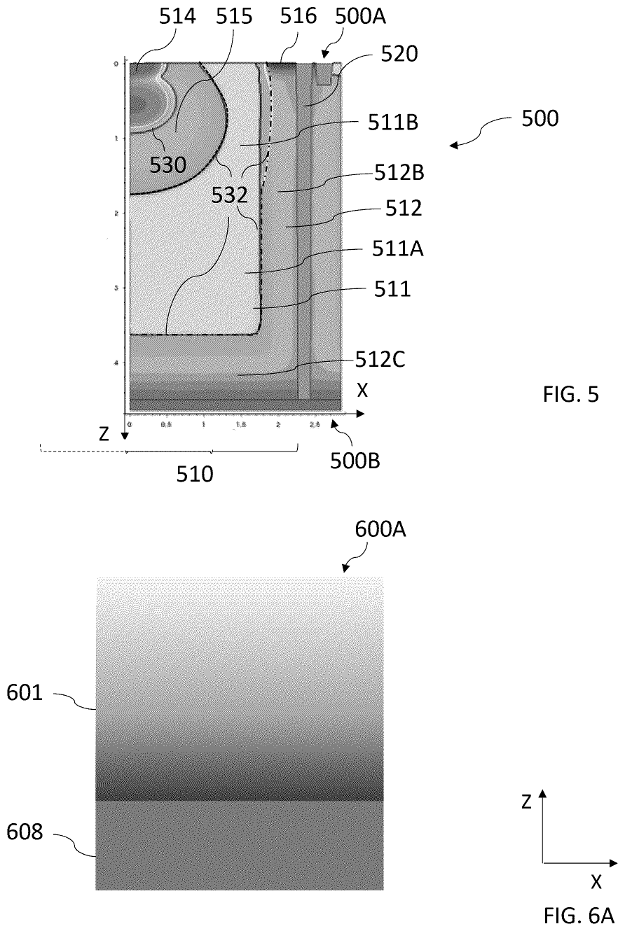

For example, fourth region 214 has a cylindrical shape. In other words, fourth region 114 may have, in top view, a round or oval shape. Similarly, fifth region 215 may have a cylindrical shape. As a variant, the fourth region and/or the fifth region may have other shapes, for example, in top view, the shape of a quadrilateral or of a quadrilateral having rounded angles, or a substantially hemispherical shape, or may comprise a portion of substantially hemispherical shape, as shown for example in FIG. 5 described hereafter.

The coupling between the fourth region and the fifth region provides a top PN junction 230, or main PN junction. For a SPAD photodiode operation, the PN junction may be reverse-biased beyond the breakdown voltage, to form an electric field around the PN junction sufficient for a photogenerated carrier reaching the multiplication area to trigger an avalanche phenomenon.

The area surrounded in dotted lines substantially corresponds to a multiplication region 231, that is, a region where the electric field is sufficiently strong for the avalanche phenomenon to have a high probability of occurring.

As shown in FIG. 2, a guard ring region 217 may surround fourth region 214. Guard ring region 217 is an N-type semiconductor region, more lightly doped than fourth region 214. Guard ring region 217 particularly enables to avoid a premature start of the photodiode at the periphery of the main PN junction, and to decrease the probability of minority carriers originating from the periphery of the junction. For example, guard ring region 217 has the shape of a round or oval ring, the shape of a square frame or of a square frame having rounded angles.

Photodiode 200 also comprises a sixth heavily-doped P-type semiconductor region 216, preferably more heavily doped than second region 212, flush with the upper surface 200A of photodiode 200, and laterally located around and at a distance from guard ring region 217. This sixth region may be a contacting region. For example, sixth region 216 has, in top view, the shape of a round or oval ring, the shape of a square frame or of a square frame having rounded angles, or more widely the shape of a quadrilateral or of a quadrilateral having rounded angles.

Fourth region 214, fifth region 215, sixth region 216, and guard ring region 217 are preferably formed by ion implantation, for example at least partially in the third region 213.

Semiconductor regions 211, 212, 213, 214, 215, 216, 217 are for example made of silicon.

The semiconductor regions are located in a well 210 delimited by a deep trench insulation 220 (DTI). For example, trench 220 surrounds well 210. For example, trench 220 has, in top view, the shape of a round or oval ring, the shape of a square frame or of a square frame having rounded angles, or more widely the shape of a quadrilateral or of a quadrilateral having rounded angles. As a variant, trench 220 has any closed shape.

For example, the trench may be filled with a conductive or semiconductor element, such as metal or polysilicon, insulated from the rest of the photodiode by an insulator layer. Trench 220 may thus form a capacitive deep trench insulation (CDTI).

The surfaces in contact of first 211 and second 212 regions form PN junctions complementary to main PN junction 230. These complementary junctions enable to form depletion areas 232, schematically shown by the curve in stripe-dot lines, and to create electric field lines in depth in the photodiode, with as a corollary the acceleration of the transport of the photogenerated carriers in the most critical areas of the photodiode, at the bottom of the photodiode for example, towards the multiplication area. Indeed, the transport of the photogenerated carriers in a depleted area is faster than in a non-depleted area.

These complementary junctions will thus be able to generate holes, which will also be able to take part in the avalanche phenomenon, as a complement to the contribution of the electrons of the main PN junction. Indeed, the holes are collected via anode 222 (described hereafter) and the anode is directly coupled, by P-type doping continuity, to the P-type regions adjacent to these complementary junctions.

As compared with the photodiode 100 of FIG. 1, this enables to extend the depletion area towards the bottom of the photodiode, and thus to accelerate the transport of the photogenerated carriers in the most critical areas of the photodiode, at the bottom of the photodiode for example. Indeed, in photodiode 200, the photogenerated carriers already being present in depletion area 232, or at least in its close neighborhood, they have a higher probability of joining the multiplication area within a shorter delay than in the case of the photodiode 100 of FIG. 1 where the depletion area was more distant from the bottom of the photodiode. As a corollary, the depletion area 232 of photodiode 200 may enable to decrease the time jitter, even when the height of the photodiode increases.

For example, photodiode 200 forms a SPAD photodiode of fully depleted type.

For example, first region 211 forms a collection volume within which carriers have a significant probability of being generated on absorption of a photon. For example, the carriers which are photogenerated in first region 211 may be driven towards a multiplication region 231, and this, all the more efficiently as the electric field lines are optimized.

Advantageously, the doping of first epitaxial region 211 may be adjusted to optimize the field lines. As described hereafter, first epitaxial region 211 may have a substantially constant doping in the Z direction, or a gradual doping in the Z direction, for example a doping decreasing between the upper surface 200A of the photodiode and the lower surface 200B of the photodiode.

As shown in FIG. 2, first region 211 may comprise a first portion 211A and a second portion 211B narrower than first portion 211A and coupling first portion 211A to third region 213. Such a shape may correspond to a funnel shape favoring the conduction of the photogenerated carriers towards multiplication region 231.

Further, second region 212 may comprise:
a first portion 212A laterally located between the second portion 211B of first region 211 and deep trench insulation 220;
a second portion 212B (lateral portion) laterally located between the first portion 211A of first region 211 and deep trench insulation 220; and
a third portion 212C (buried portion) located under first region 211, between first region 211 and the lower surface 200B of photodiode 200.

Second region 212 may vertically extend towards the upper surface 200A of photodiode 200 to also be laterally located between third region 213 and deep trench insulation 220.

The presence of the third portion 212C of second N-type region 212 under first N-type region 211 enables to form a passivation area of photodiode 200, for example so that it is less impacted by the dark current, likewise for the presence of the second portion 212B of second P-type region 212 between first N-type region 211 and deep trench insulation 220. For example, this enables to decrease the dark count rate (“DCR”).

Preferably, the width and/or the height of first epitaxial region 211 is optimized so that the volume of this first region is as large as possible, and thus to be able to collect as many photons as possible, for example, to be able to increase photon detection probability PDP, while keeping a distance on the one hand with the lower surface 200B of photodiode 200 and on the other hand with deep trench insulation 220 sufficient to limit dark counting rate DCR. For example, the second portion 212B of second region 212 has a width in the order of some hundred nanometers, the third portion 212C of second region 212 has a height in the order of from a few hundreds of nanometers to one micrometer, the dimensions of first epitaxial region 211 being deduced from the dimensions of the second and third portions of second region 212, and from the dimensions of the diode. As a non-limiting example, first epitaxial region 211 may have a width of approximately 5 μm and a height of approximately 7 μm.

Photodiode 200 also comprises a cathode 221 and an anode 222.

Cathode 221 is located in front of fourth region 214. Cathode 221 is, for example, located on top of and in contact with fourth region 214, or with a contacting area located inside, or on top of, fourth region 214. For example, cathode 221 substantially has a parallelepipedal or cylinder shape.

Anode 222 is located in front of sixth region 216. Anode 222 is, for example, located on top of and in contact with sixth region 216, or with a contacting area located inside or on top of sixth region 216. Preferably, anode 222 has, in top view, a shape similar to the shape of sixth region 216.

For example, for the shown photodiode, for which the first conductivity type is type N and the second conductivity type is type P, in operation, the anode is connected to ground and the bias voltage is applied to the cathode.

As a variant, if the first conductivity type is type P and the second conductivity type is type N with an inversion of the anode and of the cathode, in operation, the cathode is connected to ground and a bias voltage is applied to the anode.

For example, photodiode 200 is comprised, in top view, in a square having a side length smaller than 6 μm. For example, the height of photodiode 200 is in the range from approximately 3 to 15 μm, for example equal to approximately 6 μm or equal to approximately 10 μm.

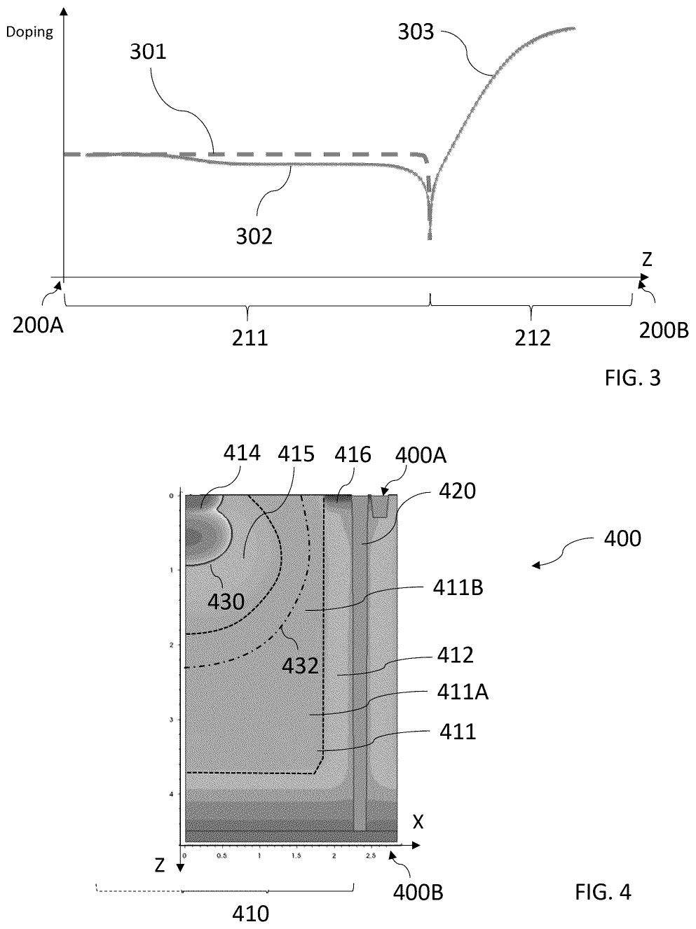

FIG. 3 illustrates is very simplified fashion doping profiles, in arbitrary unit, of the first epitaxial region and of the second semiconductor region of a photodiode similar to the photodiode 200 of FIG. 2. The doping profile is determined in the Z direction, according to a substantially laterally centered vertical line (shown in dotted lines in FIG. 2).

First N-type epitaxial region 211 may have a substantially constant N doping, particularly in the Z direction. This is illustrated in FIG. 3 by curve 301 in dotted lines.

As a variant, the doping of first epitaxial region 211 may be gradual in the Z direction, for example decrease between the upper surface 200A of the photodiode and the lower surface 200B of the photodiode, for example from 10¹⁵cm⁻³ to 5.10¹⁴ cm⁻³. This is illustrated in

FIG. 3 by the curve in full line 302.

Curve 303 shows a gradual P doping of second region 212, more precisely of the third portion 212C of the second region located under first region 211, which increases between first region 211 and the lower surface 200B of photodiode 200, for example from 2.10¹² cm⁻³ to 9.10¹⁸ cm⁻³.

The inventors could show by simulations that a photodiode according to an embodiment, for example of the type of the photodiode 200 of FIG. 2, enables to increase the population of carriers which trigger an avalanche within a very short time. They have further shown that it can be acted on the constant N doping of the epitaxial region to act on the operation of the photodiode, and that a gradual N doping profile of the epitaxial region enables to further increase the population of carriers which trigger an avalanche within a very short time, to decrease the avalanche starting time, and thus decrease the time jitter. The inventors have also shown that a photodiode with no portion of P-type region under the N-type epitaxial region still further enables to increase the population of carriers which trigger an avalanche within a very short time and to decrease the time jitter. However, as described hereafter, it may have the disadvantage of increasing the dark counting rate DCR.

FIG. 4 is a partial and simplified cross-section view showing another example of photodiode 400. Only half of the photodiode in the X direction is shown. Photodiode 400 can be distinguished from photodiode 100 mainly by the shapes of first epitaxial region 411 and of second region 412, both of the same conductivity type, type P in the example. Further, photodiode 400 comprises no guard ring region. Second region 412 may be gradually doped with a doping decreasing from lower surface 400B to first region 411.

Second region 412 surrounds first region 411, and comprises surfaces in contact with surfaces of first region 411.

Photodiode 400 further comprises a fourth heavily-doped N-type semiconductor region 414 flush with the upper surface 400A of photodiode 400, and a fifth heavily-doped P-type semiconductor region 415, in contact with, and surrounding, fourth region 414, the coupling between fourth region 414 and fifth region 415 providing a top PN junction 430, or main PN junction.

Photodiode 400 also comprises a sixth heavily-doped P-type semiconductor region 416 flush with the upper surface 400A of photodiode 400, also corresponding to an upper surface of second region 412, and located around first region 411.

First region 411 comprises a first portion 411A located under fifth region 415 and a second portion 411B laterally located between fifth region 415 and second region 412 and extending all the way to the upper surface 400A of photodiode 400.

The semiconductor regions are located in a well 410 delimited by a deep trench insulation 420.

FIG. 5 is a partial and simplified cross-section view showing a photodiode 500 according to another embodiment. Only one half of the photodiode in the X direction is shown. Photodiode 500 can be distinguished from the photodiode 400 of FIG. 4 mainly in that first epitaxial region 511 is of type N, instead of being of type P.

The surfaces in contact of the first 511 and second 512 regions form PN junctions complementary to main PN junction 530, formed by the coupling between the fourth region 514 and the fifth region 515 of photodiode 500. These complementary PN junctions enable to form a depletion area 532 schematically shown by the curve in stripe-dot lines, which extends more towards the bottom of photodiode 500 than the depletion area 432 of the photodiode 400 of FIG. 4. For example, as shown, first region 511 surrounds main PN junction 530.

The semiconductor regions are located in a well 510 delimited by deep trench insulation 520.

First region 511 comprises a first portion 511A located under fifth region 515 and a second portion 511B laterally located between fifth region 515 and second region 512 and extending all the way to the upper surface 500A of photodiode 500.

Second region 512 comprises a lateral portion 512B between first region 511 and deep trench insulation 520, and a buried portion 512C between first region 511 and the lower surface 500B of photodiode 500.

The inventors could show by simulations that a photodiode according to an embodiment, with complementary PN junctions, for example of the type of the photodiode 500 of FIG. 5, enables to create electric field lines in deeper regions of the photodiode as compared with a photodiode of the type of the photodiode 400 of FIG. 4, with no complementary PN junction.

The inventors could also show by simulations that a photodiode according to an embodiment, for example of the type of the photodiode 500 of FIG. 5, enables to increase the height of the photodiode without increasing the avalanche starting time. Conversely, the inventors could observe that for a photodiode of the type of the photodiode 400 of FIG. 4, the fact of increasing its height significantly increases the avalanche starting time.

Thus, a photodiode according to an embodiment enables to increase the height of the photodiode, and thus to have a larger collection volume for an equal width, for example to increase the photon detection probability (PDP), without increasing the time jitter.

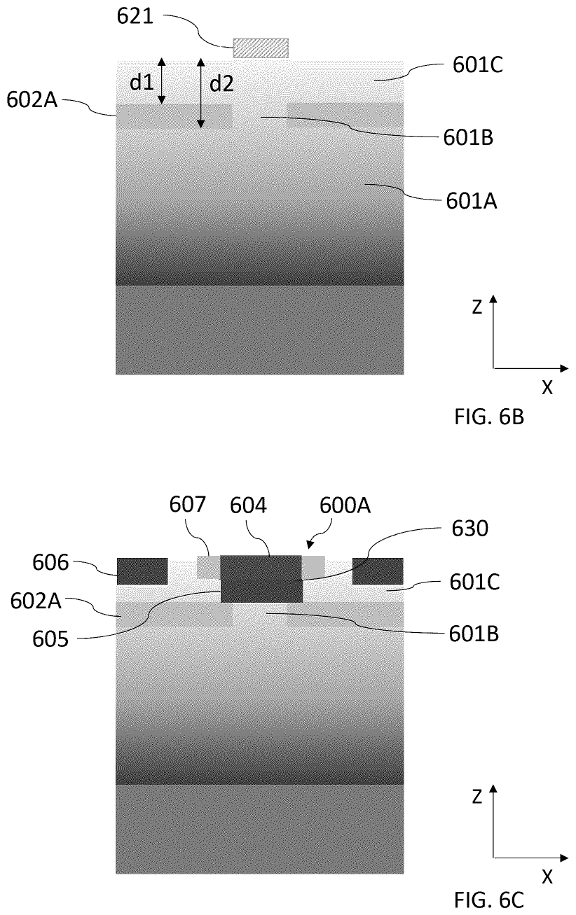

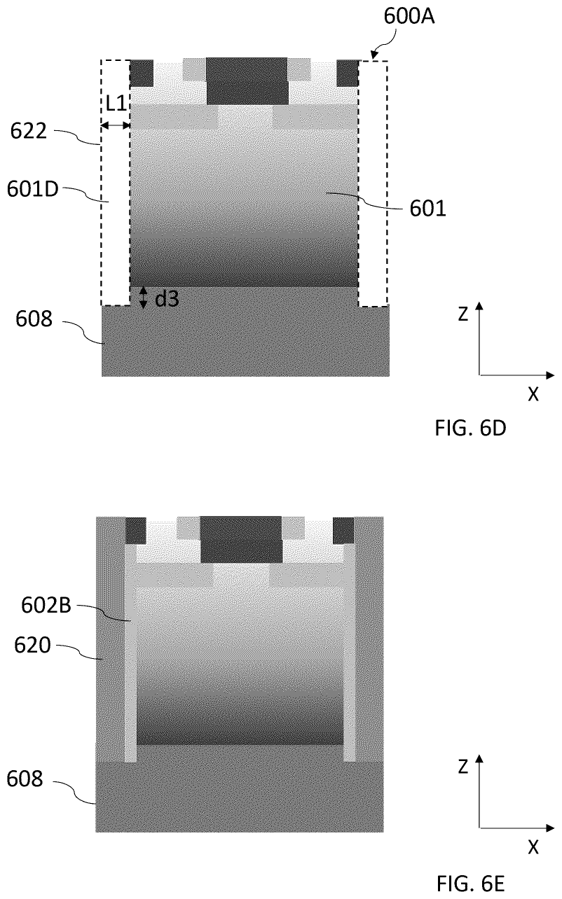

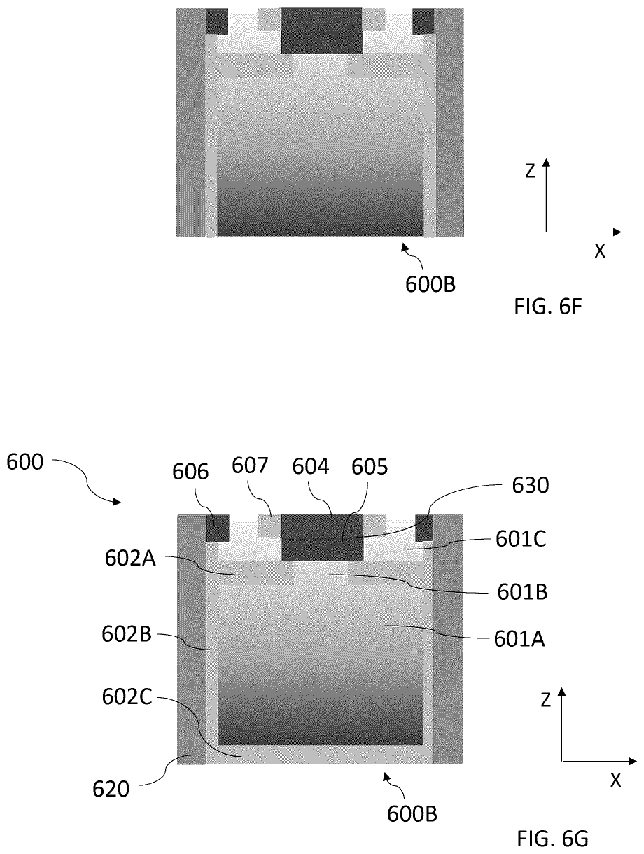

FIG. 6A, FIG. 6B, FIG. 6C, FIG. 6D, FIG. 6E, FIG. 6F, and FIG. 6G are cross-section views showing steps of a method of manufacturing a photodiode according to an embodiment.

FIG. 6A shows a structure obtained at the end of a step of epitaxial growth on a substrate 608, for example a silicon substrate (Si), forming an epitaxial layer 601 of a first conductivity type, type N in the shown method example. The epitaxial growth may be carried out at a constant doping concentration, or at a gradual doping concentration in the Z direction, for example a doping concentration decreasing between the upper surface 600A of the photodiode and substrate 608. Epitaxial layer 601 enables to form the future first N-type region.

FIG. 6B shows a structure obtained at the end of a step of doping by ion implantation, to form, in epitaxial layer 601, a first portion 602A of the second conductivity type (first portion of the second region), type P in the shown method example.

First portion 602A is, for example, formed from a distance d1 to a distance d2 from the upper surface 600A of the photodiode, for example by configuring the parameters of the ion implantation to allow this implantation between d1 and d2.

First P-type portion 602A delimits a first portion 601A of the N-type epitaxial layer (first portion of the first region) located under first P-type portion 602A and a third portion 601C of the N-type epitaxial layer located above first portion 602A.

The ion implantation in epitaxial layer 601 to form first portion 602A may be performed through a mask 604, for example a mask obtained by photolithography. For example, mask 604 is adapted so that first portion 602A is ring-shaped, that is, while keeping a second portion 601B of N-type epitaxial layer 601 (second portion of the first region) at the center of first P-type portion 602A.

This second N-type portion 601B enables the first region to be funnel-shaped, which enables to favor the conduction of photogenerated carriers from the first portion 601A of the first region to the top PN junction 630 described hereafter.

FIG. 6C shows a structure obtained at the end of a plurality of steps of doping by ion implantation, to form, in the third portion 601C of epitaxial layer 601:
a heavily-doped N-type region 604 (fourth region) and a heavily-doped P-type region 605 (fifth region), said fourth and fifth regions forming a top PN junction 630, N-type region 604 being flush with the upper surface 600A of photodiode 600 and topping P-type region 605;
a guard ring region 607 located around N-type region 604, and less heavily N doped than region 604;
a heavily-doped P region 606 (sixth region) flush with upper surface 600A, laterally formed around and at a distance from guard ring region 607.

N-type region 604 and P-type region 605 may be formed above the second portion 601B of epitaxial layer 601, or even partially extend above first P-type portion 602A.

Each ion implantation may be performed through a mask (not shown), for example a mask obtained by photolithography, and then removed after ion implantation.

FIG. 6D shows a structure obtained at the end of a step of etching across a width L1 of a lateral edge 601D along the entire periphery of epitaxial layer 601 from the upper surface 600A of the photodiode, the etching for example continuing down to a depth d3 in silicon substrate 608.

This forms a lateral trench 622. As a variant, the etching may be carried out all the way to the limit between silicon substrate 608 and epitaxial layer 601.

FIG. 6E shows a structure obtained at the end of:
a step of filling of lateral trench 622 with an insulating material, for example silicon dioxide (SiO₂), to form a deep trench insulation 620; and
a step of forming of a second P-type portion 602B (second portion of the second region) laterally between deep trench insulation 620 and the etched epitaxial layer 601.

For example, deep trench insulation 620 surrounds the previously-formed regions.

For example, second P-type portion 602B forms a passivation area of the photodiode, for example so that it is less impacted by the dark current.

For example, the forming of second portion 602B may be performed, according to the desired passivation type:
by doping, for example by ion implantation;
by adding a doping material or a charge-inversion material in the insulating material during the filling of lateral trench 622.

Thus, the conductivity along deep trench insulation 620 may be inverted with no ion implantation by the use of a specific material.

FIGS. 6A to 6E show that deep trench insulation 620 is formed after the doping steps. This is not limiting, and, as a variant, the deep trench insulation may be formed before the doping steps.

FIG. 6F shows a structure obtained at the end of a step of etching of substrate 608.

FIGS. 6A to 6F show that deep trench insulation 620 is formed before the step of etching of substrate 608. This is not limiting, and, as a variant, the deep trench insulation may be formed after this step of etching of the substrate. Further, the deep trench insulation may be formed from the lower surface 600B of the photodiode.

FIG. 6G shows a structure obtained at the end of an optional step of forming of a third P-type portion 602C (third portion of the second region).

Third P-type portion 602C may be formed by doping, for example by ion implantation, for example from the lower surface 600B of the photodiode.

As a variant, third P-type portion 602C may be formed by epitaxial growth, in this case before the forming by epitaxial growth of N-type epitaxial layer 601.

For example, third P-type portion 602C forms a passivation area of the photodiode, for example so that it is less impacted by the dark current.

The obtained photodiode 600 shown in FIG. 6G is similar to the photodiode 200 of FIG. 2.

Based on the above-described manufacturing method example, those skilled in the art may adapt the method to manufacture other photodiodes according to the embodiments, for example the photodiode 500 of FIG. 5.

Thus, an advantage of the described embodiments is that the photodiode can be formed without for this to complicate the manufacturing method.

Another advantage of the described embodiments is that they adapt to photodiodes of small size, for example, having side lengths shorter than 6 μm, and/or to photodiodes having a height for example in the range from 4 to 10 μm, or even more.

Another advantage of the described embodiments is that they enable to decrease the size, for example the width, of the photodiode without for this to degrade the photon detection probability and/or to increase the time jitter.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

Avalanche photodiode (200; 500) may be summarized as including a main PN junction (230; 530) adapted to being reverse-biased; and a plurality of semiconductor regions including at least: a first epitaxial semiconductor region (211; 511) of a first conductivity type; and a second semiconductor region (212; 512) of the second conductivity type, said second region being arranged to at least partially surround the first region, and comprising surfaces in contact with surfaces of said first region.

Method of manufacturing an avalanche photodiode (600), may be summarized as including a main PN junction (630) adapted to being reverse-biased, the method including the forming of a plurality of semiconductor regions including at least: a first epitaxial semiconductor region of a first conductivity type; and a second semiconductor region of the second conductivity type, said second region being arranged to at least partially surround the first region, and comprising surfaces in contact with surfaces of said first region.

The main PN junction (230; 530) may be formed by fourth (214; 514) and fifth (215; 515) regions of the plurality of semiconductor regions; the fourth region being more heavily doped with the first conductivity type, for example more heavily doped than the first region, and being formed from a first surface (200A; 500A) of the photodiode; and the fifth region being heavily doped with the second conductivity type, for example more heavily doped than the second region, and being formed under, and in contact with, the fourth region; the fourth and fifth regions being for example located at the center of the photodiode in a plane parallel to the first surface.

A sixth region (216; 516) of the plurality of semiconductor regions may be laterally formed around, and at a distance from, the fourth region (214; 514) from the first surface (200A; 500A) of the photodiode, the sixth region being heavily doped with the second conductivity type, for example more heavily doped than the second region.

A third semiconductor region (213) of the plurality of semiconductor regions may be formed between the first surface (200A) of the photodiode and the first region (211), the third region being an epitaxial region of the first conductivity type, and the fourth, fifth, and sixth regions (214, 215, 216) being formed by doping, for example by ion implantation, in said third region.

The first and third regions may be epitaxially grown and doped in similar conditions, for example corresponding to regions of a same epitaxial layer.

A guard ring region (217) of the plurality of semiconductor regions may be formed around the fourth region (214), the guard ring region being of the first conductivity type and being more lightly doped than the fourth region (214).

The semiconductor regions may be formed in a well (210; 510) delimited by a deep trench insulation (220; 520) extending in a direction (Z) perpendicular to the first surface (200A; 500A) of the photodiode.

The second region (212; 512) may include a lateral portion (212B; 512B) located between the first region (211; 511) and the deep trench insulation (220; 520).

The second region (212; 512) may include a buried portion (212C; 512C) located between the first region (211; 511) and a second surface (200B; 500B) of the photodiode opposite to the first surface.

The first region (211) may be doped in substantially constant fashion in a direction (Z) perpendicular to the first surface (200A) of the photodiode.

The first region (511) may be gradually doped in a direction (Z) perpendicular to the first surface (500A), for example in decreasing fashion between said first surface and a second surface (500B) of the photodiode opposite to the first surface.

The first region (211) may include a first portion (211A) and a second portion (211B) narrower, in a plane parallel to the first surface (200A), than the first portion, and located between the first portion (211A) and the main PN junction (230).

The first region (511) surrounds the main PN junction (530), for example, may include a first portion (511A) located under the main PN junction (530), and a second portion (511B) extending all the way to the first surface (500A) of the photodiode (500).

The first region may be inside of the second region.

Each dimension of the photodiode, in a plane parallel to a first surface (200A) of the photodiode, may be smaller than 6 μm and/or the height of the photodiode is in the range from 3 to 15 μm, for example in the range from 6 to 10 μm.

The forming of the plurality of semiconductor regions may include the forming by epitaxial growth of an epitaxial layer (601) of the first conductivity type intended to form the first semiconductor region; then the forming, by partial doping of the epitaxial layer, for example by ion implantation, of at least one first portion (602A) of the second region; and the fourth region and the fifth region are formed by partial doping of the epitaxial layer, for example by ion implantation, from the first surface (600A) of the photodiode.

The lateral portion (602B) of the second region may be formed by partial doping of the epitaxial layer, for example by ion implantation, by partial change of conductivity of the epitaxial layer, by diffusion from the deep trench insulation, or by a charge-inversion material in the deep trench insulation.

The buried portion (602C) of the second region may be formed by epitaxial growth, or by partial doping of the epitaxial layer, for example by ion implantation, from the second face (600B) of the photodiode.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An avalanche photodiode, comprising:
a main PN junction adapted to being reverse-biased; and
a plurality of semiconductor regions including at least:
a first epitaxial semiconductor region of a first conductivity type;
a second semiconductor region of the second conductivity type, said second region being arranged to at least partially surround the first region, and comprising surfaces in contact with surfaces of said first region; and
a third semiconductor region.

2. The photodiode according to claim 1, wherein:
the main PN junction is formed by fourth and fifth regions of the plurality of semiconductor regions;
the fourth region being heavily doped with the first conductivity type, for example more heavily doped than the first region, and being formed from a first surface of the photodiode; and
the fifth region being heavily doped with the second conductivity type, and being formed under, and in contact with, the fourth region;
the fourth and fifth regions being located at the center of the photodiode in a plane substantially parallel to the first surface.

3. The photodiode according to claim 2, wherein a sixth region of the plurality of semiconductor regions is laterally formed around, and at a distance from, the fourth region from the first surface of the photodiode, the sixth region being heavily doped with the second conductivity type.

4. The photodiode according to claim 3, wherein the third semiconductor region of the plurality of semiconductor regions is formed between the first surface of the photodiode and the first region, the third region being an epitaxial region of the first conductivity type, and the fourth, fifth, and sixth regions being formed by doping.

5. The photodiode according to claim 2, wherein a guard ring region of the plurality of semiconductor regions is formed around the fourth region, the guard ring region being of the first conductivity type and being more lightly doped than the fourth region.

6. The photodiode according to claim 2, wherein the semiconductor regions are formed in a well delimited by a deep trench insulation extending in a direction perpendicular to the first surface of the photodiode.

7. The photodiode according to claim 6, wherein the second region comprises a lateral portion located between the first region and the deep trench insulation.

8. The photodiode according to claim 2, wherein the second region comprises a buried portion located between the first region and a second surface of the photodiode opposite to the first surface.

9. The photodiode according to claim 2, wherein the first region is doped in substantially constant fashion in a direction perpendicular to the first surface of the photodiode.

10. The photodiode according to claim 2, wherein the first region is gradually doped in a direction perpendicular to the first surface.

11. The photodiode according to claim 2, wherein the first region comprises a first portion and a second portion narrower, in a plane parallel to the first surface, than the first portion, and located between the first portion and the main PN junction.

12. The photodiode according to claim 2, wherein the first region surrounds the main PN junction, including a first portion located under the main PN junction, and a second portion extending all the way to the first surface of the photodiode.

13. The photodiode according to claim 1, wherein the first region is inside of the second region.

14. The photodiode according to claim 1, wherein each dimension of the photodiode, in a plane parallel to a first surface of the photodiode, is smaller than 6 μm and/or the height of the photodiode is in the range from 3 to 15 μm.

15. A method, comprising:
manufacturing an avalanche photodiode having a main PN junction adapted to being reverse-biased, the method including:
forming of a plurality of semiconductor regions including at least:
forming a first epitaxial semiconductor region of a first conductivity type; and
forming a second semiconductor region of the second conductivity type, said second region being arranged to at least partially surround the first region, and comprising surfaces in contact with surfaces of said first region.

16. The method of claim 15 comprising:
forming a third semiconductor region of the plurality of semiconductor regions between the first surface of the photodiode and the first region, the third region being an epitaxial region of the first conductivity type;
forming by fourth and fifth regions of the plurality of semiconductor regions;
forming the fourth region being more heavily doped with the first conductivity type than the first region;
forming the fifth region being heavily doped with the second conductivity type and being formed under, and in contact with, the fourth region; and
forming the fourth and fifth regions being located at the center of the photodiode in a plane substantially parallel to the first surface.

17. The method according to claim 16, wherein the forming of the plurality of semiconductor regions comprises:
the forming by epitaxial growth of an epitaxial layer of the first conductivity type intended to form the first semiconductor region; then
the forming, by partial doping of the epitaxial layer, for example by ion implantation, of at least one first portion of the second region; and
the fourth region and the fifth region are formed by partial doping of the epitaxial layer, for example by ion implantation, from the first surface of the photodiode.

18. The method according to claim 17, wherein the lateral portion of the second region is formed by partial doping of the epitaxial layer, by partial change of conductivity of the epitaxial layer, by diffusion from the deep trench insulation, or by a charge-inversion material in the deep trench insulation.

19. The method according to claim 17, wherein the buried portion of the second region is formed by epitaxial growth, or by partial doping of the epitaxial layer, from the second face of the photodiode.
